(19) United States
(12) Patent Application Publication
(10) Pub. No.: US 2009/0171606 A1
(43) Pub. Date: Jul. 2, 2009

(54) SEMICONDUCTOR MANUFACTURE PERFORMANCE ANALYSIS

(76) Inventors: Takahiro Murata, Beaverton, OR (US); Kedar Dongre, Hillsboro, OR (US); Yiqing Zhou, Portland, OR (US); Mark Armstrong, Portland, OR (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/968,132

(22) Filed: Dec. 31, 2007

(51) Int. Cl. G06F 19/00; G01R 31/26

(52) U.S. Cl. 702/82; 702/81

(57) ABSTRACT

A software architecture, design and implementation that enables efficient transistor performance analysis across multiple levels of parameter granularity with interactive drill-down, drill-across capability, for use during semiconductor technology development. The software may include several features, such as highly modular, robust architecture to enable analysis across the multiple granularity of transistor performance data, i.e., per die, material group, and aggregate, GUI-based template configuration to specify the analysis across the multiple levels in a uniform set of operations, subsystems to execute the template specified with the GUI, integration of pass-fail analysis analytics, interactive drill-down on particular data points of user interest in automatically generated charts, and drill-across capability allowing linking of data points highlighted on a single chart to those that are correlated in all other charts. Other embodiments are described.

### FIELD

This application relates generally to semiconductor manufacturing. In particular, this application relates to tools for analyzing and optimizing semiconductor design and performance.

### BACKGROUND

A primary challenge of semiconductor manufacture is to determine the optimal transistor architecture within the ranges of key constraints that produces the best combination of optimal performance and manufacturability. Prototype transistor architectures are manufactured across varying geometries and processing values, and thousands of parameters, both physical and electrical, are collected for tens of locations across each of tens of wafers that form a run of experiment. A conventional manner of device analysis is to prepare a certain set of spreadsheets that specifies the data to be extracted from the database along with the application of statistics functions per material grouping and the charting of raw data. Such specification is fed into the scripts/spreadsheet macros that extract the required data, forming the material grouping, apply the statistics functions, and generate the charts. Certain custom analysis on the resulting data may be available, but requires a separate set of specifications and another round of execution. The conventional device analysis automation is deficient because it only achieves automation in a fragmentary manner such as only per module—e.g., MOS, Salicide, scribeline, etc.—where no integrated, uniform operation is supported and only at one level, mainly per material grouping (e.g., per wafer), leaving out the analysis that would be necessary to comprehend the entire data space. It does not support problematic trend investigation by bringing in new perspectives (for example the location sensitivity), and how related test structure and/or location is performing in other groups and other tests.

### BRIEF DESCRIPTION OF THE DRAWINGS

The following description can be better understood in light of Figures, in which:

FIG. 1 is a schematic illustration of an exemplary embodiment of an analysis tool;

FIG. 2 is a schematic flow chart of a data pipeline in an exemplary embodiment of an analysis tool; and

FIG. 3-8 illustrate graphical representations of data presented by an exemplary embodiment of an analysis tool.

Together with the following description, the Figures demonstrate and explain the principles of the methods, tools, systems, apparatus and methods described herein. In the Figures, the thickness and configuration of components may be exaggerated for clarity. The same reference numerals in different Figures represent the same component.

### DETAILED DESCRIPTION

The following description supplies specific details in order to provide a thorough understanding. Nevertheless, the skilled artisan would understand that the methods, systems and devices described herein can be implemented and used without employing these specific details. Indeed, the devices, systems, and associated methods can be placed into practice by modifying the systems and methods and can be used in conjunction with any apparatus and techniques conventionally used in the industry.

In the early phases of technology development if semiconductors, the data being collected is prone to significant variations both within wafer and across wafers. In analyzing this large volume of data with significant variations, the following are critical and may be provided in a single solution according to some embodiments described herein: (a) faster info-turn; and (b) that the mode of variations is to be made explicitly visible, and presented in a manner conducive to the identification of the cause of such variations. In this context of device/transistor performance analysis, the problem of what the essential automation primitives are and how they should be put together as a software tool may be addressed by embodiments described herein. Specifically, the same embodiments allow a user to define the data analysis that spans across the multiple levels of granularity inherent to the subject, i.e., per die, material group, and aggregate, with an easy-to-use software package with a graphical user interface (GUI), yet in a declarative style, allowing the user to specify concisely what is being analyzed at each level of granularity and how the output is used in other analyses and graphical presentations.

Additionally, a user may efficiently form the data set that flows through the multiple levels, by extracting, filtering, and aligning a large volume of data, both electrical and physical parameters, then forming an analysis pipeline that encompasses multiple types of analyses for different modules (MOS, Salicide, scribeline, etc.), and for different business needs (e.g., transistor matching). A typical execution may involve over 250 sets of die-level parameters per polarity across a run of 25 wafers, resulting in over 100,000 raw data points per run, generating thousands of statistics function application instances and thousands of charts during the course.

Also, a user may exercise analytics that determine the value where the correlated indicator crosses a given threshold, which is made available across the multiple levels of analysis, regardless of the types of analyses conducted. A user may also exercise engineering judgment through the graphical results, identifying ad-hoc range of focus, carrying out further analysis on it.

Some functionality and features for software architecture, design and implementation that enable efficient transistor performance analysis across multiple levels of parameter granularity with interactive drill-down, drill-across capability, for use during semiconductor technology development that may be provided in some embodiments may include: drill-down on selected data points from the charts generated by the software, rendering those points in wafer maps and a radial chart, to enable the visualization of variation mode; linking of the data points selected on a single chart with those that share properties of interest across all other charts, to facilitate identifying correlated effects; highly modular, robust software architecture with uniform data model that is amenable to introduction of new analytics while insulating the analysis tool software logic from the variations of commercial-off-the-shelf (COS) components; template configuration user interface (UI) that allows for analysis that spans across the multiple levels—per die through the aggregate results based on material grouping—to be specified while making the output of one level, interspersed with the formulas thereof, usable in the next level via simple, uniform operations, e.g., drag-and-drop, copy-and-paste, and auto-fill; a single automated execution of the specification that produces analyses for multiple modules (e.g., MOS, Salicide, scribeline, etc.) and for various business needs (e.g., transistor matching); and integration of analytics across all the levels that determines the value where the correlated indicator crosses a given threshold.

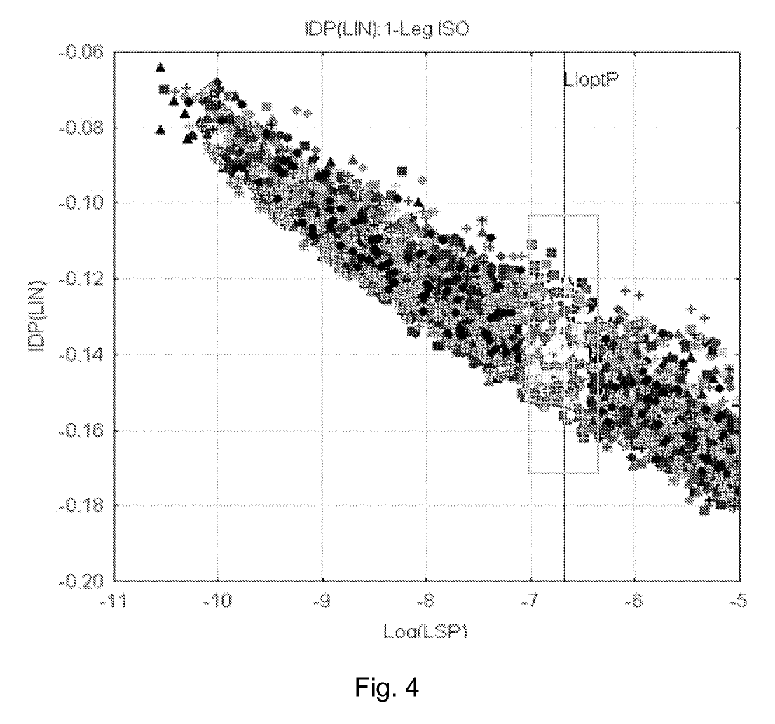

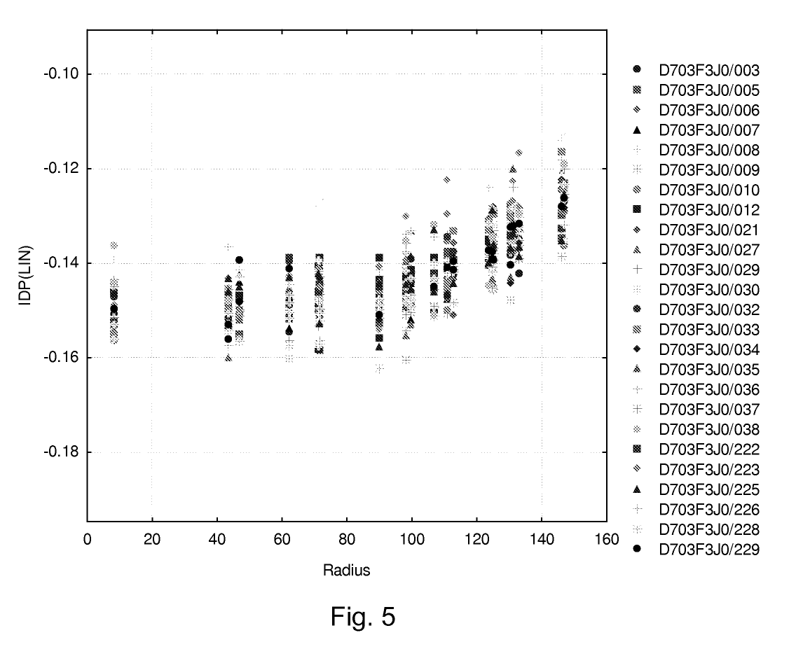

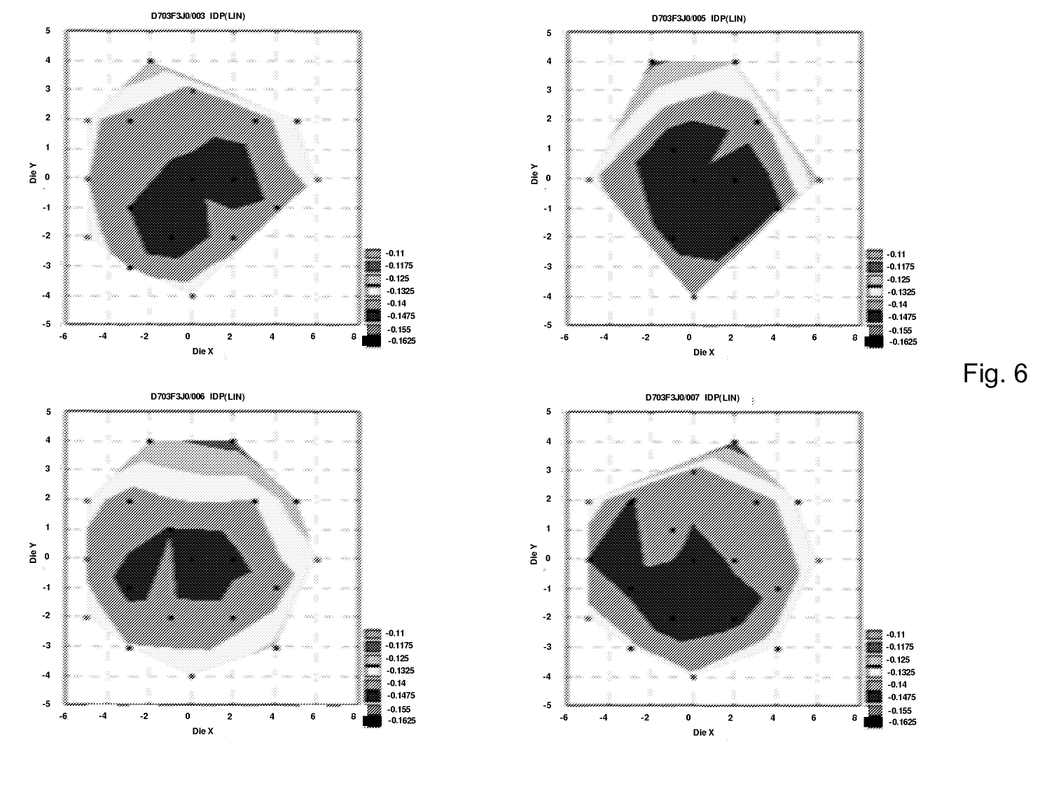

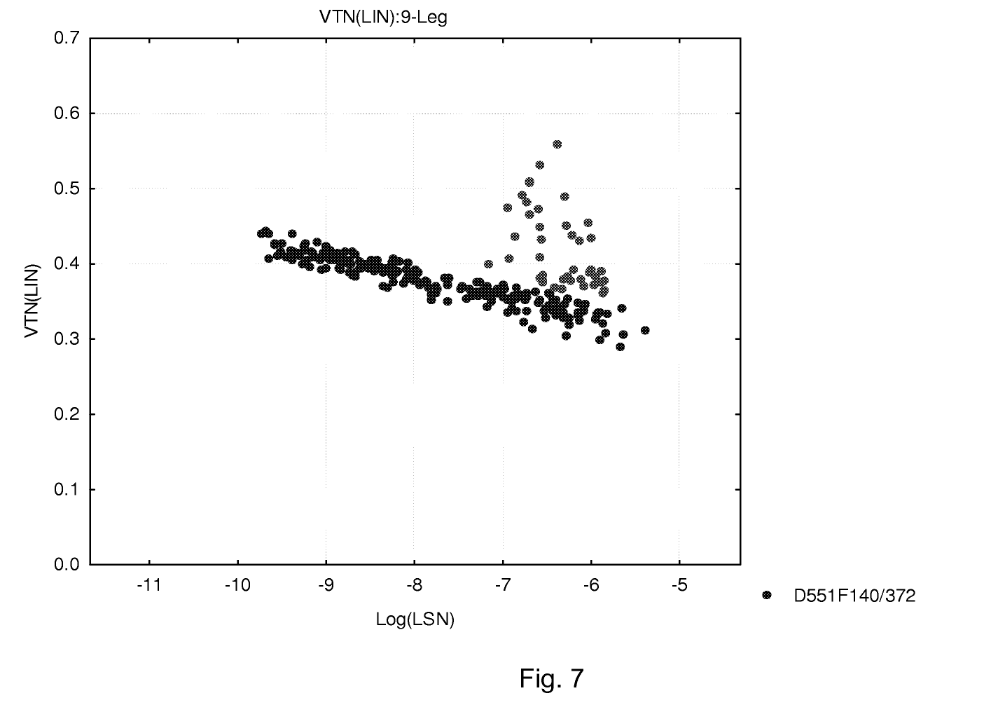

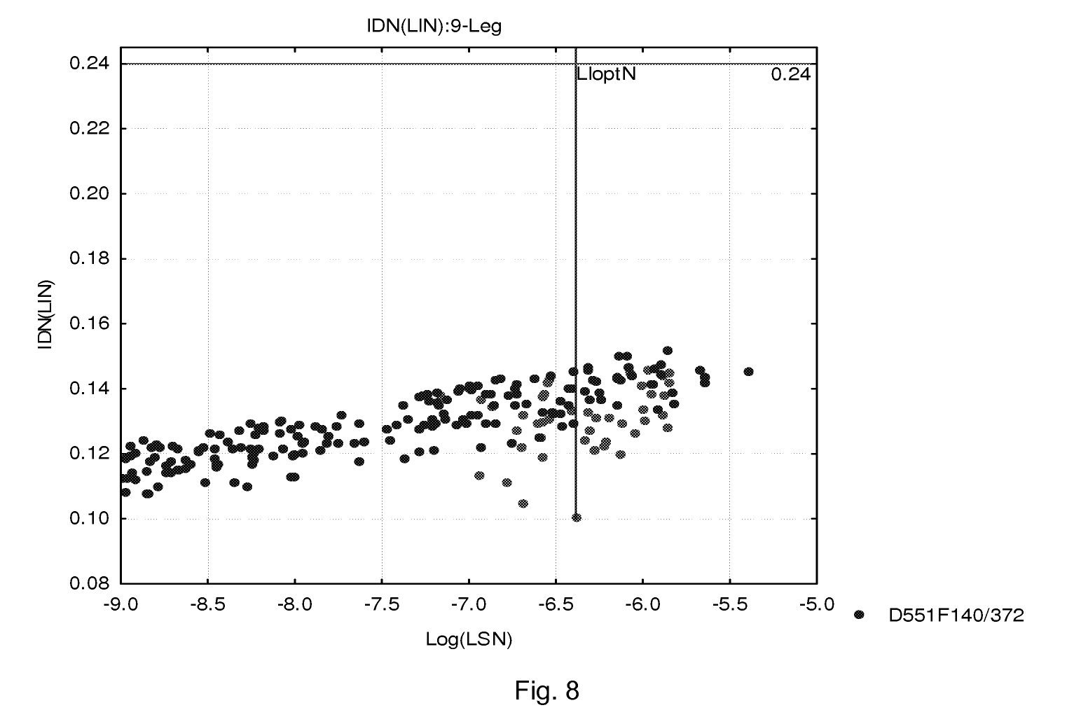

Some embodiments may include analysis tools that include: highly modular, robust architecture to enable analysis across the multiple granularity of transistor performance data, i.e., per die, material group, and aggregate, that are inherent to the subject; GUI-based template module to specify the analysis across the multiple levels in a uniform set of operations where the output of one level is fed into the next; execution subsystem modules to execute the template specified with the GUI in a pipeline fashion based on uniform data representation including data extraction, analysis (statistics function application), and charting for visualization and interactive analysis; an analysis module that allows for integration of analytics called pass-fail analysis (FIG. 3), which computes the value of a variable where the correlated variable crosses a certain threshold; interactive drill-down based on the data points of user focus in the automatically generated performance data chart (FIG. 4), leading to the generation of wafer-map (FIG. 6) and radial chart (FIG. 5); and graph-linking (FIGS. 7-8), where data points may be highlighted on a single chart (FIG. 7), to have those that share certain critical properties in all other charts (FIG. 8 as one of such charts), providing drill-across capability.

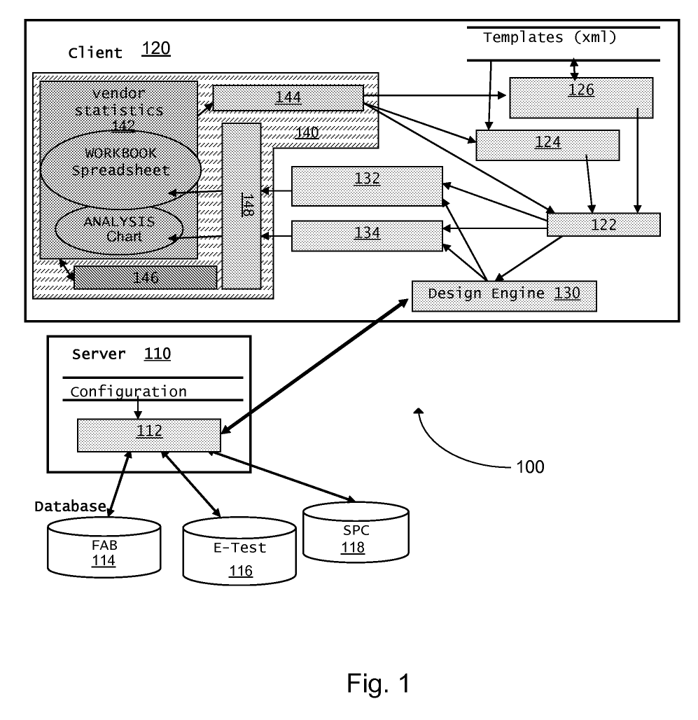

Turning to the figures, FIG. 1 illustrates a schematic view of an exemplary configuration of software modules and hardware in analysis tool 100 according to some embodiments. Analysis tool 100 may be employed on a server 110 and a client 120 computers. Server 110 may include data extractor module 112 to interface with fabrication database (FAB) 114, E-test database 116, and statistical process control (SPC) 118. Data extractor module 112 may provide access to and organization of data stored in databases 114, 116, 118 for use by other modules of analysis tool 100. Client computer 120 may run execution engine module 130, along with user interface (UI) logic module 122, execution UI module 124, template maker UI module 126, data manipulation module 132, analysis/chart module 134, and output/interaction module 140. Client computer 120 may also include templates 128 in memory to allow a user to easily create and use common analysis charts and input parameters. Templates 128 may be in xml format.

Output/interaction module 140 may include vendor statistics module 142, which may allow for packaging and display of workbook spreadsheets and analysis charts presenting specific data points and data trends resulting from analysis tool 100. Additionally, output/interaction module 140 may include interface add-in module 144, event handler module 146, and framework abstraction layer module 148. Each module may be present as illustrated in FIG. 1. Additionally, in some embodiments, each module and component described may be resident in a plurality of computers, as well as packaged together into other modules or further divided into additional function-specific modules.

Analysis tool 100 may be provided such that it carefully insulates the device analysis from the underlying output/interaction module 140 as a vehicle to carry out the analysis. FIG. 1 depicts this effect by showing that dashed area for output/interaction module 140 contains all the vendor software dependent modules. All the logical requirements that control which statistics functions need to be applied and which charts to be generated based on the various data sets are implemented by the modules outside of output/interaction module 140. This architectural framework may allow our control/execution logic to remain independent of vendor statistics software module 142.

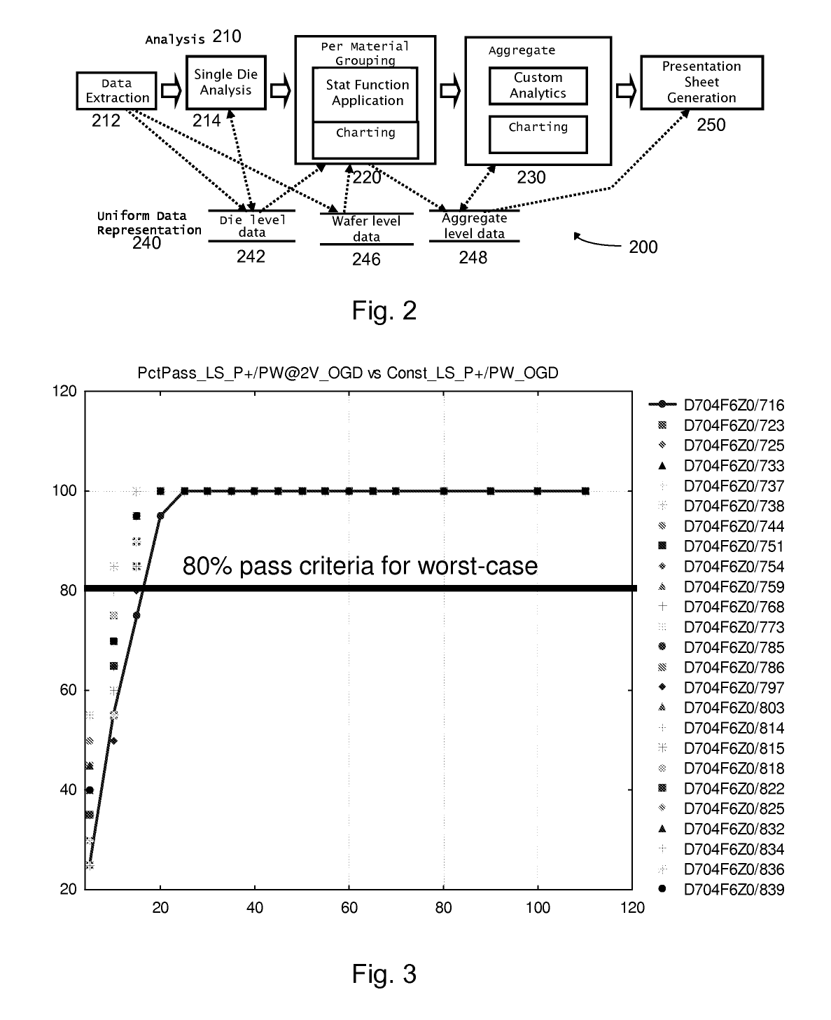

In some embodiments, analysis tool 100 may provide pipeline 200 for analyzing and generating usable data as illustrated in FIG. 2. In FIG. 2, a block arrow represents the flow of execution, from one step to the next, while a dotted arrow represents the flow of data. Raw performance data from a production wafer may be imported into analysis 210, via data extraction module 212, which forms usable fields and groupings under uniform data representation scheme 240. Analysis 210 consists of a number of stages, 214, 220, 230, towards presentation sheet generation 250, which utilizes the data components 242, 246, and 248. FIGS. 3-8 are graphical representations that may represent data analysis and grouping as desired by a user of analysis tool 100 and presented from data in steps 240, 242, 246, 248, 250 described below.

Data for each die on the wafer may be analyzed per die in single die analysis 214 and presented in die level data 242. Similarly, wafer level data may be analyzed per material grouping 220 and presented in wafer level data 246 and aggregate level data 248 for multiple wafers in a production process. Per material grouping 220, stat function application and charting may also be executed to organize and further analyze collected data. Aggregate grouping 230 may be presented in aggregate level data 248 and may also provide for custom analytics and charting as desired by one of ordinary skill in the art. Uniform data representation 240, including die level data 242, wafer level data 246, and aggregate level data 248 may then be used to general presentation sheets in presentation sheet generation step 250.

In some embodiments, data may be provided by analysis tool 100 through use of template maker UI module 126 by users, such as engineers and technicians to specify the analytics to be applied to E-Test data from database 116 and data extraction module 112, including statistics function application, chart generation, correlating to the FAB measurement data as well as split conditions. The particular analytics specification desired by a user may be provided in templates 128. Execution UI module 124 may provide for a Graphical User Interface (GUI) to allow a user to easily specify the material to be analyzed (lots and wafers), to organize the grouping thereof, and then to invoke the execution of the analysis and charting as specified in the template. Execution UI module 124 may interact with the execution engine 130, data manipulation module 132, and analysis/chart module 134, thru user interface control logic 122. The GUI may support the prefetching of parameter names to be rendered for analysis from the E-Test 116, FAB 114, and SPC 118 databases, based on any desired characterizing input, such as the ID of the lot that is measured for the target tests. The prefetched parameters may be placed in a graphically represented reservoir in the GUI, to be dragged and dropped graphically into particular analysis groupings, with ad-hoc filtering being applied.

In some embodiments, the data grouping to which certain analytics is applied may range from die level data 242, to wafer level data 246, to aggregate level data derived from the material group. The user may specify what needs to be done, while the GUI identifies the output variables from one level and presents them to be used further. The GUI may also support the notion of test family, where a series of E-Test parameters (and custom parameters such as constants and formulas) may be referenced by a single “family name”, which can be used in any parts of the template as if it were a single parameter name. This may provide a convenience in defining tens if not hundreds of kinds of charts, and conciseness in understanding what the analytics defined in the template is intended for.

Execution UI module 124 may be used to execute the analytics as specified in a selected template from templates 128, where the execution may form pipeline 200 based on uniform data representation 240, from data extraction 212, along with the augmentation thereof, through single die analysis 214, per material grouping 220, to aggregate grouping 120. During the processing, the custom formulas may also be evaluated based on the results at the given data level (i.e., die level data 242, wafer level data 246, aggregate level data 248), which in turn may become part of the input to the next level. Such analytics can in effect encompass multiple types of analyses and charting, arising from the multiple modules, e.g., MOS, Salicide, scribeline, etc., and the business needs, e.g., transistor matching.

In some embodiments, based on uniform data representation 242, analysis stages 212, 214, 220, 240 may be pipelined coherently, which may also enable straightforward introduction of new analytics, such as a “pass-fail” analysis example as shown in FIG. 3, where each of the data points in FIG. 3 represents a particular transistor, die, wafer, group of wafers, or any other data grouping desired by a user. The “pass-fail” analysis may provide an overall idea of the efficiency and performance of a particular production or design process. For example, a “pass-fail” analysis may be used to determine the dimension where the certain leakage starts to go beyond the tolerable threshold in an integrated manner, at the die level, the material grouping level, and at the aggregate level. In particular, die level data 242 can be fed into the analysis per material grouping 220, as well as into a wafer map, as shown in FIG. 6, in contrast to a set of the minimum sizes where the wafers showing 80% of dies pass, all of which may be in turn supported by a single algorithm and the common data structure across the entire system. In some embodiments, any level of pass or fail for any parameter may be selected.

In some embodiments, analysis tool 100 may provide drill-down capability. Drill-down capability may include the selection of data points to be made interactively in a performance data chart, FIG. 4, and then have the selected data points presented in a certain, different context; in particular either in a radial chart mapping the die radius, FIG. 5, or in a wafer/contour map, FIG. 6. FIG. 4 illustrates the capability of focusing on a region of interest (represented by LIoptP box), which may then be used to generate a radial chart, as shown in FIG. 5, or wafer/contour maps, as shown in FIG. 6, of the data selected from the performance data chart, as shown in FIG. 4.

Similarly, analysis tool 100 may provide graph-linking capability, allowing the selection of data points to be made interactively, along with the choice of any desired property or properties of concern, in die-location or test structure or both, then have the data points that share the property of concern in all the charts presented with the marker/style also chosen interactively, illustrated in FIGS. 7 and 8. For example, FIG. 7 illustrates a threshold voltage chart when particular selected outliers are represented with a lighter shade. FIG. 8 represents a drain current chart where the selected outliers from FIG. 7 are shown with the same lighter shade. This allows a user to critically analyze various levels of performance and determine correlations between various types of data and data tests.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A method of analyzing semiconductors, comprising:
collecting data associated with semiconductor processing;
providing the data to an analysis program configured to be stored on computer readable media;
extracting a desired portion of the data using the analysis program, wherein the desired portion of the data is associated with one or more of
a die on the wafer,
a wafer, and
a plurality of wafers;
analyzing the desired portion of the data using the analysis program;
generating a first chart associated with the desired portion of the data;
providing user-controllable selection of the first chart to select particular data points of interest from the desired portion of the data; and
performing at least one of:
generating a second chart associated with the particular data points of interest, and
analyzing the particular points of interest with respect to at least one of the die on the wafer, the wafer, and a plurality of wafers.

2. The method of claim 1, wherein the analysis program includes:
a template module,
a user interface module,
an execution engine module,
a data extractor module, and
an analysis module.

3. The method of claim 2, wherein the user interface module comprises:
a template maker user interface module;
a execution user interface module; and
a user interface control logic module.

4. The method of claim 2, wherein the data extractor module is in communication with the execution engine module and at least one of a FAB database, a E-test database, and a SPC database.

5. The method of claim 2, wherein the analysis module is configured to provide data to a vendor software module configured to perform the generating the first chart and the generating the second chart.

6. The method of claim 2, wherein at least some of the modules of the analysis program are configured to run separately on a plurality of computers in communication with each other.

7. The method of claim 1, wherein the analyzing the desired portion includes analysis on a die level, wafer level, and aggregate level.

8. The method of claim 7, wherein the analyzing includes statistics function application.

9. The method of claim 1, further comprising, providing a graphical user interface configured to provide a user control of at least one of the collecting, the providing the data, the extracting a desired portion of the data, the analyzing the desired portion of the data, and the generating a first chart.

10. A data analysis tool, comprising:
at least one computer;
a vendor statistics program running on the at least one computer;
an analysis program running on the at least one computer, the analysis program being configured to interact with and remain separate from the vendor statistics program, and wherein the analysis program includes user-defined templates to determine the specific analysis output;
at least one database in communication with the at least one computer;
wherein the analysis program is configured to analyze data from semiconductor manufacturing on a die level, wafer level, and aggregate level; and
wherein the analysis program and the vendor statistics program are configured to cooperate to produce a plurality of charts based on the data analyzed by the analysis program.

11. The tool of claim 10, wherein the at least one database includes at least one of a FAB database, an E-test database, and an SPC database.

12. The tool of claim 10, wherein the analysis program is configured to provide a pass-fail analysis based on user-defined pass-fail criteria and the specific analysis output.

13. The tool of claim 10, wherein the analysis program is configured to integrate analytics of each of the die level, the wafer level, and the aggregate level to determine a value where a correlated indicator crosses a user-selected threshold value.

14. The tool of claim 10, wherein the analysis program and the vendor statistics program are configured such that data points highlighted on one of the plurality of charts are correlated in all related charts of the plurality of charts.

15. The tool of claim 10, wherein the analysis program is configured to be accessed by a user with a GUI.
